(19) United States
(12) Patent Application Publication
(10) Pub. No.: US 2026/0301816 A1
(43) Pub. Date: Oct. 1, 2026

(54) FLASH MEMORY DEVICE

(71) Applicant: Winbond Electronics Corp., Taichung City (TW)

(72) Inventor: Chung-Zen Chen, HsinChu (TW)

(73) Assignee: Winbond Electronics Corp., Taichung City (TW)

(21) Appl. No.: 19/437,355

(22) Filed: Dec. 31, 2025

(30) Foreign Application Priority Data
Mar. 27, 2025 (TW) 114111736

(51) Int. Cl. G11C 16/08; G11C 16/10; G11C 16/26; G11C 16/34

(52) U.S. Cl. CPC G11C 16/08; G11C 16/10; G11C 16/26; G11C 16/3459

(57) ABSTRACT

A flash memory device is provided. The flash memory device includes a memory array, bit lines, a first decoder, a sense circuit, and a second decoder. The first decoder receives an address signal, and selects multiple target memory cells according to the address signal. The second decoder receives the address signal and a flag signal, and divides multiple sense amplifiers in the sense circuit into multiple sense amplifier groups. In multiple stages after failing a programming verification, the second decoder sequentially selects multiple of the sense amplifier groups according to the address signal and the flag signal. A number of the target memory cells corresponding to the sense amplifiers selected in one of the stages is greater than or equal to a number of the target memory cells corresponding to the sense amplifiers selected in others of the stages.

### CROSS-REFERENCE TO RELATED APPLICATION

This application claims the priority benefit of Taiwan application serial no. 114111736, filed on Mar. 27, 2025. The entirety of the above-mentioned patent application is hereby incorporated by reference herein and made a part of this specification.

### BACKGROUND

### Technical Field

The disclosure relates to a memory device, and more particularly to a flash memory device.

### Description of Related Art

Low-density NOR flash memory products (<=32 Mb) usually use 8-bit or 16-bit to execute programming operations, while high-density NOR flash memory products usually use 16-bit or 32-bit to execute programming operations. If more bits are programmed at one time, programming current simultaneously generated becomes higher. However, the computing speed required for electronic products is expected to become faster and faster in the future. Under the premise that a memory is generally operated with a bit length of 2 to the power of N, if the number of bits that may be simultaneously programmed is increased in units of 2 to the power of N in order to reduce programming time, programming current will also exponentially increase.

### SUMMARY

The disclosure provides a flash memory device, which can be programmed with the number of bits that is not 2 to the power of N.

A flash memory device of the disclosure includes a memory array, multiple bit lines, a first decoder, a sense circuit, and a second decoder. The memory array includes multiple memory regions. Each of the memory regions includes multiple memory cells. The bit lines are respectively coupled to the memory cells. The first decoder is coupled to the bit lines and is configured to receive an address signal, and select multiple target memory cells from the memory cells according to the address signal. The sense circuit includes multiple sense amplifiers. An input terminal of each of the sense amplifiers is coupled to the first decoder. The second decoder is coupled to an output terminal of each of the sense amplifiers and is configured to receive the address signal and a flag signal, and divide the sense amplifier into multiple sense amplifier groups. In multiple stages after failing a programming verification, the second decoder sequentially selects multiple of the sense amplifier groups according to the address signal and the flag signal, so that the corresponding target memory cells are applied with a programming voltage. A number of the target memory cells corresponding to the sense amplifiers selected in one of the stages is greater than or equal to a number of the target memory cells corresponding to the sense amplifiers selected in others of the stages.

Based on the above, the flash memory device of the disclosure may be programmed with the number of bits that is not 2 to the power of N to reduce the amplitude of increase in programming current when the number of bits to be simultaneously programmed is increased, thereby taking both programming speed and the programming current into consideration.

In order for the features and advantages of the disclosure to be more comprehensible, the following specific embodiments are described in detail in conjunction with the drawings.

### BRIEF DESCRIPTION OF THE DRAWINGS

FIG. 1 is a block schematic diagram of a flash memory device according to an embodiment of the disclosure.

FIG. 2 is a partial circuit schematic diagram of a first decoder according to an embodiment of the disclosure.

FIG. 3A and FIG. 3B are circuit schematic diagrams of a control circuit according to an embodiment of the disclosure.

FIG. 4A is a circuit schematic diagram of a third switch circuit according to an embodiment of the disclosure.

FIG. 4B is a circuit schematic diagram of a fourth switch circuit according to an embodiment of the disclosure.

FIG. 5 is a step flowchart of a programming method according to an embodiment of the disclosure.

### DESCRIPTION OF THE EMBODIMENTS

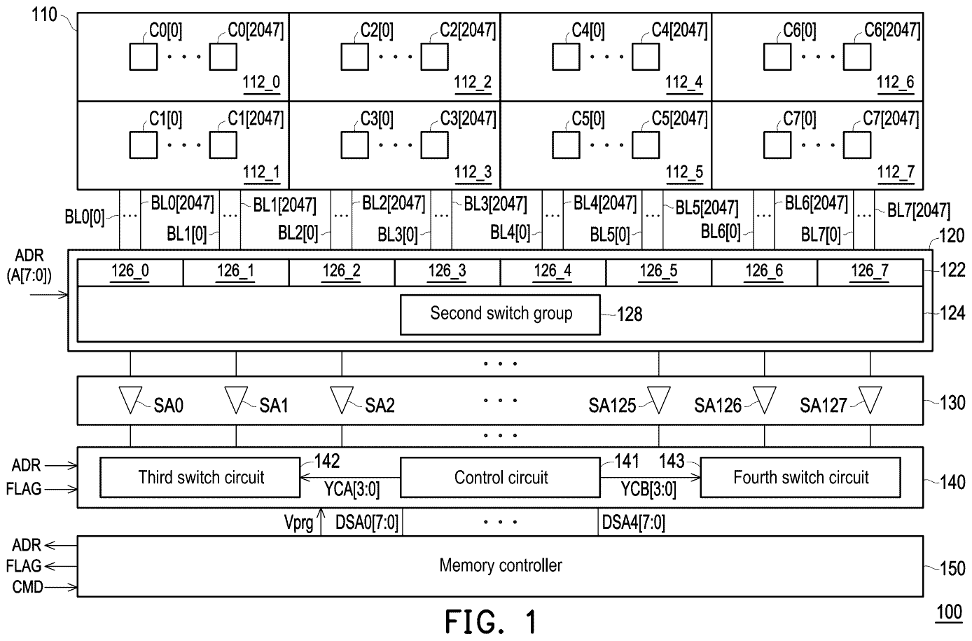

Please refer to FIG. 1. A flash memory device 100 includes a memory array 110, a first decoder 120, a sense circuit 130, a second decoder 140, and a memory controller 150. The memory array 110 is, for example, an ETOX NOR flash memory array. The memory array 110 includes multiple memory regions 112_0 to 112_7. Each of the memory regions 112_0 to 112_7 includes 2048 memory cells respectively coupled to 2048 bit lines. Specifically, memory cells C0[0] to C0[2047] in the memory region 112_0 are respectively coupled to bit lines BL0[0] to BL0[2047], memory cells C1[0] to C1[2047] in the memory region 112_1 are respectively coupled to bit lines BL1[0] to BL1[2047], and so on. For the convenience of description, the bit lines BLK[0] to BLK[2047] are collectively referred to as bit lines BLK below, where K is 0 to 7.

The first decoder 120 is coupled to bit lines BL0 to BL7. The first decoder 120 may receive an address signal ADR, and select multiple target memory cells from, for example, multiple memory cells in a memory region selected by a word line decoder according to the address signal ADR. The sense circuit 130 includes sense amplifiers SA0 to SA127. An input terminal of each of the sense amplifiers SA0 to SA127 is coupled to the first decoder 120.

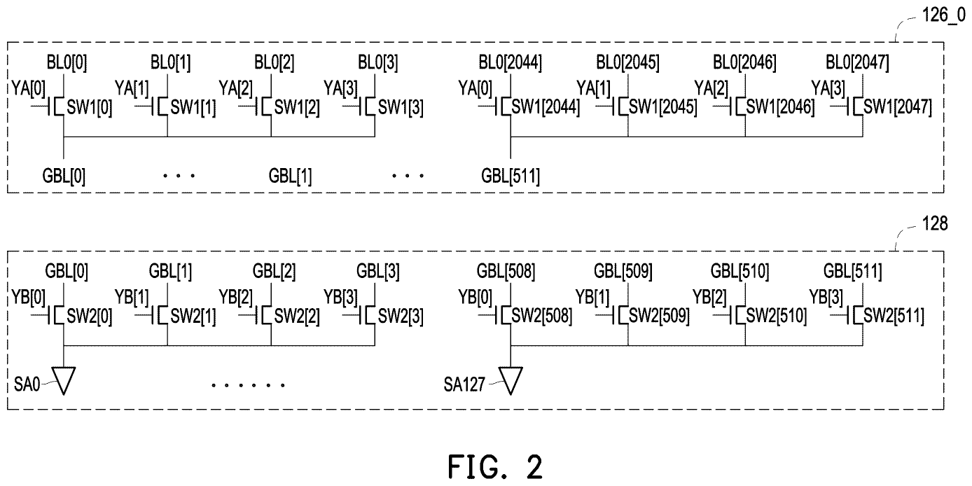

The following embodiment illustrates implementation details of the first decoder 120. Please refer to FIG. 1 and FIG. 2. The first decoder 120 includes a first switch circuit 122 and a second switch circuit 124. The first switch circuit 122 includes first switch groups 126_0 to 126_7, and the second switch circuit 124 includes a second switch group 128. Each of the first switch groups 126_0 to 126_7 is coupled between a corresponding bit line and common bit lines GBL[0] to GBL[511]. The second switch group 128 is coupled between the common bit lines GBL[0] to GBL[511] and input terminals of the sense amplifiers SA0 to SA127 in the sense circuit 130.

The first decoder 120 may decode the address signal ADR (decodable into a bit value A[7:0]) to provide first selection signals YA[0] to YA[3] to each of the first switch groups 126_0 to 126_7 and second selection signals YB[0] to YB[3] to the second switch group 128 according to a first bit value group A[3:0] in the address signal ADR. A bit value A[1: 0] in the first bit value group A[3:0] may be decoded into the first selection signals YA[0] to YA[3], so that one of the first selection signals YA[0] to YA[3] is at a high logic level (logic value 1) and the other three are at a low logic level (logic value 0). A bit value A[3:2] in the first bit value group A[3:0] may be decoded into the second selection signals YB[0] to YB[3], so that one of the second selection signals YB[0] to YB[4] is at a high logic level and the other three are at a low logic level.

Taking the first switch group 126_0 as an example, in FIG. 2, the first switch group 126_0 includes switches SW1[0] to SW1[2047]. The switches SW1[0] to SW1[2047] are respectively coupled between the bit lines BL0[0] to BL0[2047] and the common bit lines GBL[0] to GBL[511]. Taking FIG. 2 as an example, first terminals of the switches SW1[0] to SW1[3] are respectively coupled to the bit lines BL0[0] to BL0[3], and second terminals of the switches SW1[0] to SW1[3] are commonly coupled to the common bit line GBL[0]. The switches SW1[0] to SW1[3] of the first switch group 126_0 may select one of the bit lines BL0[0] to BL0[3] to couple to the common bit line GBL[0] according to the first selection signals YA[0] to YA[3].

Similarly, first terminals of the switches SW1[2044] to SW1[2047] are respectively coupled to the bit lines BL0[2044] to BL0[2047], and second terminals of the switches SW1[2044] to SW1[2047] are commonly coupled to the common bit line GBL[511]. The switches SW1[2044] to SW1[2047] of the first switch group 126_0 may select one of the bit lines BL0[2044] to BL0[2047] to couple to the common bit line GBL[511] according to the first selection signals YA[0] to YA[3].

The second switch group 128 includes switches SW2[0] to SW2[511]. The switches SW2[0] to SW2[511] are respectively coupled between the common bit lines GBL[0] to GBL[511] and the input terminals of the sense amplifiers SA0 to SA127. Taking FIG. 2 as an example, first terminals of the switches SW2[0] to SW2[3] are respectively coupled to the common bit lines GBL[0] to GBL[3], and second terminals of the switches SW2[0] to SW2[3] are commonly coupled to the input terminal of the sense amplifier SA0. The switch switches SW2[0] to SW2[3] of the second switch group 128 may select one of the common bit lines GBL[0] to GBL[3] to couple to the input terminal of the sense amplifier SA1 according to the second selection signals YB[0] to YB[3].

Similarly, first terminals of the switches SW2[508] to SW2[511] are respectively coupled to the common bit lines GBL[508] to GBL[511], and second terminals of the switches SW2[508] to SW2[511] are commonly coupled to the input terminal of the sense amplifier SA127. The switches SW2[508] to SW2[511] of the second switch group 128 may select one of the common bit lines GBL[508] to GBL[511] to couple to the input terminal of the sense amplifier SA127 according to the second selection signals YB[0] to YB[3].

The second decoder 140 is coupled to an output terminal of each of the sense amplifiers SA0 to SA127. The second decoder 140 may receive the address signal ADR and a flag signal FLAG, and divide the sense amplifiers SA0 to SA127 into multiple sense amplifier groups (for example, first sense amplifier groups SA00[7:0] to SA03[7:0], SA10[7:0] to SA13[7:0], and SA20[7:0] to SA23[7:0] and second sense amplifier groups SA30[7:0] and SA31[7:0] and SA40[7:0] and SA41[7:0]). In multiple stages (for example, a first stage ST1 and a second stage ST2) after failing a programming verification, the second decoder 140 may sequentially select multiple sense amplifier groups according to the address signal ADR and the flag signal FLAG, so that the corresponding target memory cells may be applied with a programming voltage Vprg.

Specifically, the second decoder 140 includes a control circuit 141, a third switch circuit 142, and a fourth switch circuit 143, and is coupled to the memory controller 150 via output data line groups DSA0[7:0] to DSA4[7:0]. The control circuit 141 may respectively provide a third selection signal YCA[3:0] and a fourth selection signal YCB[3:0] to the third switch circuit 142 and the fourth switch circuit 143 according to a second bit value group A[5:4] in the address signal ADR and the flag signal FLAG.

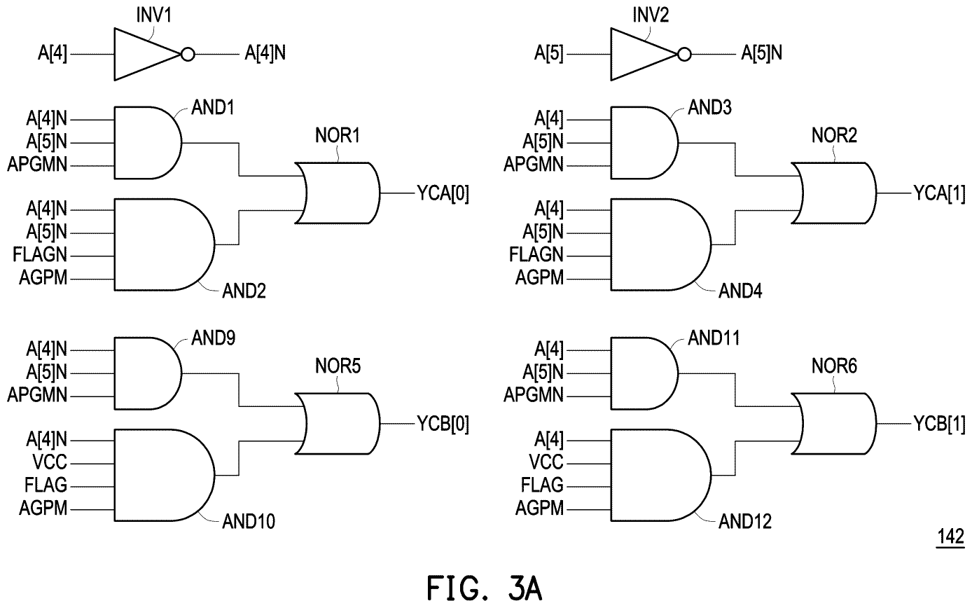

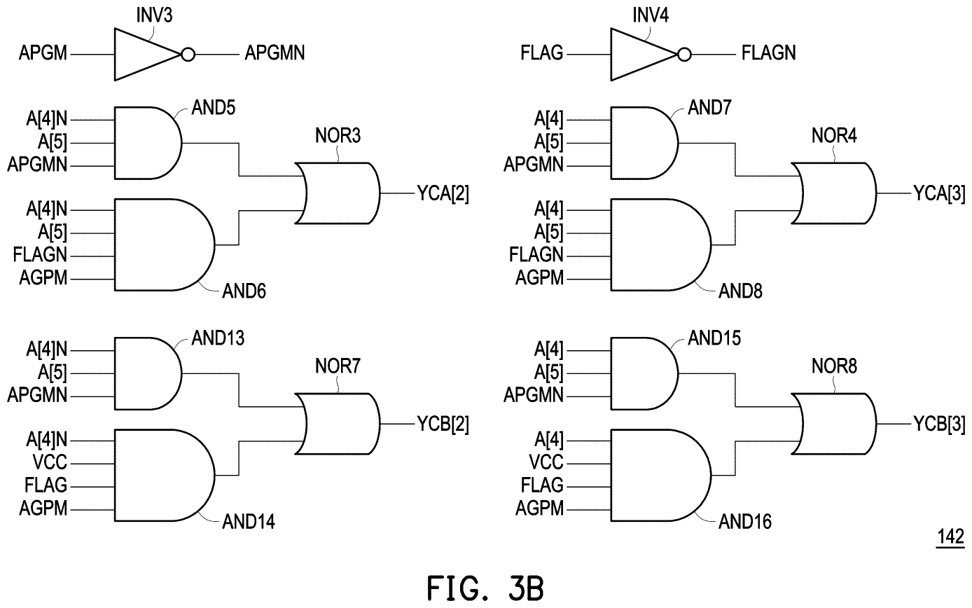

For further example, as shown in FIG. 3A and FIG. 3B, the control circuit 141 includes a first inverter INV1 to a fourth inverter INV4, a first AND gate AND1 to a sixteenth AND gate AND16, and a first OR gate NOR1 to an eighth OR gate NOR8. The second bit value group A[5:4] in the address signal ADR includes a first bit value A[4] and a second bit value A[5]. An input terminal of the first inverter INV1 receives the first bit value A[4], and an output terminal outputs an inverted first bit value A[4]N. An input terminal of the second inverter INV2 receives a second bit value A[5], and an output terminal outputs an inverted second bit value A[5]N. An input terminal of the third inverter INV3 receives a programming state signal APGM, and an output terminal outputs an inverted programming state signal APGMN. An input terminal of the fourth inverter INV4 receives the flag signal FLAG, and an output terminal outputs an inverted flag signal FLAGN. Logic states of the first bit value A[4], the second bit value A[5], the programming state signal APGM, and the flag signal FLAG are respectively complementary to logic states of the inverted first bit value A[4]N, the inverted second bit value A[5]N, the inverted programming state signal APGMN, and the inverted flag signal FLAGN.

A first input terminal of the first AND gate AND1 receives the inverted first bit value A[4]N, a second input terminal receives the inverted second bit value A[5]N, and a third input terminal receives the inverted programming state signal APGMN. A first input terminal of the second AND gate AND2 receives the inverted first bit value A[4]N, a second input terminal receives the inverted second bit value A[5]N, a third input terminal receives the inverted flag signal FLAGN, and a fourth input terminal receives the programming state signal APGM. A first input terminal of the first OR gate NOR1 is coupled to an output terminal of the first AND gate AND1, a second input terminal is coupled to an output terminal of the second AND gate AND2, and an output terminal outputs a 1st third selection signal YCA[0].

A first input terminal of the third AND gate AND3 receives the first bit value A[4], a second input terminal receives the inverted second bit value A[5]N, and a third input terminal receives the inverted programming state signal APGMN. A first input terminal of the fourth AND gate AND4 receives the first bit value A[4], a second input terminal receives the inverted second bit value A[5]N, a third input terminal receives the inverted flag signal FLAGN, and a fourth input terminal receives the programming state signal APGM. A first input terminal of the second OR gate NOR2 is coupled to an output terminal of the third AND gate AND3, a second input terminal is coupled to an output terminal of the fourth AND gate AND4, and an output terminal outputs a 2nd third selection signal YCA[1].

A first input terminal of the fifth AND gate AND5 receives the inverted first bit value A[4]N, a second input terminal receives the second bit value A[5], and a third input terminal receives the inverted programming state signal APGMN. A first input terminal of the sixth AND gate receives the inverted first bit value A[4]N, a second input terminal receives the second bit value A[5], a third input terminal receives the inverted flag signal FLAGN, and a fourth input terminal receives the programming state signal APGM. A first input terminal of the third OR gate NOR3 is coupled to an output terminal of the fifth AND gate AND5, a second input terminal is coupled to an output terminal of the sixth AND gate AND6, and an output terminal outputs a 3rd third selection signal YCA[2].

A first input terminal of the seventh AND gate AND7 receives the first bit value A[4], a second input terminal receives the second bit value A[5], and a third input terminal receives the inverted programming state signal APGMN. A first input terminal of the eighth AND gate AND8 receives the first bit value A[4], a second input terminal receives the second bit value A[5], a third input terminal receives the inverted flag signal FLAGN, and a fourth input terminal receives the programming state signal APGM. A first input terminal of the fourth OR gate NOR4 is coupled to an output terminal of the seventh AND gate AND7, a second input terminal is coupled to an output terminal of the eighth AND gate AND8, and an output terminal outputs a 4th third selection signal YCA[3].

A first input terminal of the nineth AND gate AND9 receives the inverted first bit value A[4]N, a second input terminal receives the inverted second bit value A[5]N, and a third input terminal receives the inverted programming state signal APGMN. A first input terminal of the tenth AND gate AND10 receives the inverted first bit value A[4]N, a second input terminal receives a supply voltage VCC, a third input terminal receives the flag signal FLAG, and a fourth input terminal receives the programming state signal APGM. A first input terminal of the fifth OR gate NOR5 is coupled to an output terminal of the nineth AND gate AND9, a second input terminal is coupled to an output terminal of the tenth AND gate AND10, and an output terminal outputs a 1st fourth selection signal YCB[0]. The supply voltage VCC is maintained at a high logic level (for example, 3.3 to 5V).

A first input terminal of the eleventh AND gate AND11 receives the first bit value A[4], a second input terminal receives the inverted second bit value A[5]N, and a third input terminal receives the inverted programming state signal APGMN. A first input terminal of the twelfth AND gate AND12 receives the first bit value A[4], a second input terminal receives the supply voltage VCC, a third input terminal receives the flag signal FLAG, and a fourth input terminal receives the programming state signal APGM. A first input terminal of the sixth OR gate NOR6 is coupled to an output terminal of the eleventh AND gate AND11, a second input terminal is coupled to an output terminal of the twelfth AND gate AND12, and an output terminal outputs a 2nd fourth selection signal YCB[1].

A first input terminal of the thirteenth AND gate AND13 receives the inverted first bit value A[4]N, a second input terminal receives the second bit value A[5], and a third input terminal receives the inverted programming state signal APGMN. A first input terminal of the fourteenth AND gate AND14 receives the inverted first bit value A[4]N, a second input terminal receives the supply voltage VCC, a third input terminal receives the flag signal FLAG, and a fourth input terminal receives the programming state signal APGM. A first input terminal of the seventh OR gate NOR7 is coupled to an output terminal of the thirteenth AND gate AND13, a second input terminal is coupled to an output terminal of the fourteenth AND gate AND14, and a third output terminal outputs a 3rd fourth selection signal YCB[2].

A first input terminal of the fifteenth AND gate AND15 receives the first bit value A[4], a second input terminal receives the second bit value A[5], and a third input terminal receives the inverted programming state signal APGMN. A first input terminal of the sixteenth AND gate AND16 receives the first bit value A[4], a second input terminal receives the supply voltage VCC, a third input terminal receives the flag signal FLAG, and a fourth input terminal receives the programming state signal APGM. A first input terminal of the eighth OR gate NOR8 is coupled to an output terminal of the fifteenth AND gate AND15, a second input terminal is coupled to an output terminal of the sixteenth AND gate AND16, and an output terminal outputs a 4th fourth selection signal YCB[3].

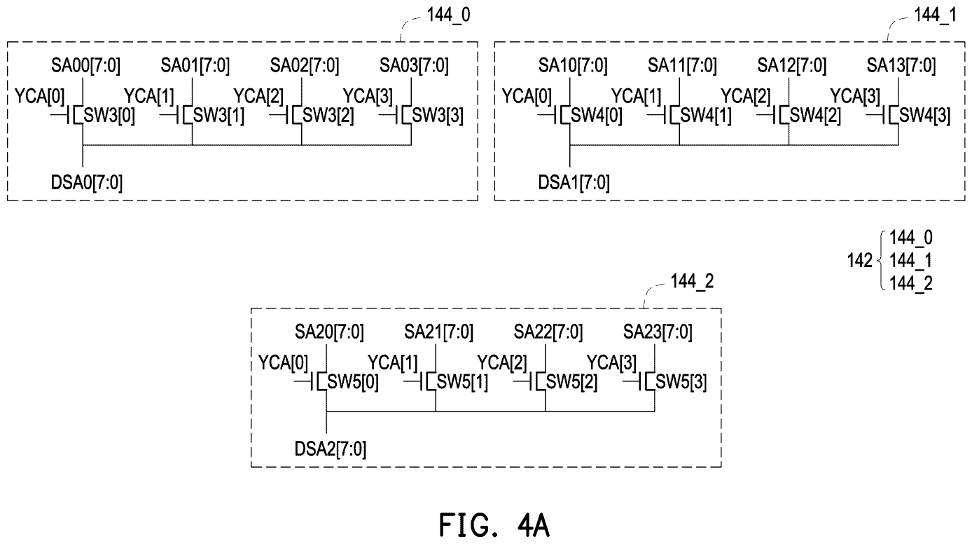

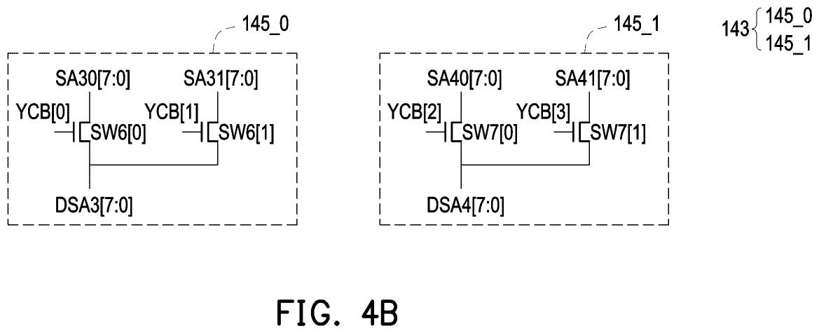

On the other hand, as shown in FIG. 4A and FIG. 4B, the third switch circuit 142 includes third switch groups 144_0 to 144_2, and the fourth switch circuit 143 includes fourth switch groups 145_0 and 145_1. In FIG. 4A, the third switch group 144_0 includes switches SW3[0] to SW3[3], the third switch group 144_1 includes switches SW4[0] to SW4[3], and the third switch group 144_2 includes switches SW5[0] to SW5[3]. The switches SW3[0] to SW3[3] are coupled between the first sense amplifier groups SA00[7:0] to SA03[7:0] and the output data line group DSA0[7:0]. The switches SW4[0] to SW4[3] are coupled between the first sense amplifier groups SA10[7:0] to SA13[7:0] and the output data line group DSA1[7:0]. The switches SW5[0] to SW5[3] are coupled between the first sense amplifier groups SA20[7:0] to SA23[7:0] and the output data line group DSA2[7:0]. In FIG. 4B, the fourth switch group 145_0 includes switches SW6[0] to SW6[1], and the fourth switch group 145_1 includes switches SW7[0] to SW7[1]. The switches SW6[0] to SW6[1] are coupled between the second sense amplifier groups SA30[7:0] and SA31[7:0] and the output data line group DSA3[7:0]. The switches SW7[0] to SW7[1] are coupled between the second sense amplifier groups SA40[7:0] and SA41[7:0] and the output data line group DSA4[7:0]. Each of the third switch groups 144_0 to 144_2 receives all the third selection signals YCA[3:0], and each of the fourth switch groups 145_0 and 145_1 receives different fourth selection signals YCB[3:0]. The fourth switch group 145_0 receives the 1st fourth selection signal YCB[0] and the 2nd fourth selection signal YCB[1], and the fourth switch group 145_1 receives the 3rd fourth selection signal YCB[2] and the 4th fourth selection signal YCB[3].

Please refer to FIG. 3A, FIG. 3B, FIG. 4A, and FIG. 4B simultaneously. The programming state signal APGM indicates whether the flash memory device 100 is in a programming state (a programming operation is being executed) and is, for example, also provided by the memory controller 150. When the programming state signal APGM is at a low logic level, it indicates that the flash memory device 100 is not in the programming state. When the programming state signal APGM is at a high logic level, it indicates that the flash memory device 100 is in the programming state. The flag signal FLAG indicates the current stage after failing the programming verification. When the flag signal FLAG is at a low logic level, it indicates that the current stage is the first stage ST1. When the flag signal FLAG is at a high logic level, it indicates that the current stage is the second stage ST2.

In operation, when the flash memory device 100 is not in the programming state, since the programming state signal APGM is at the low logic level, the second AND gate AND2, the fourth AND gate AND4, the sixth AND gate AND6, the eighth AND gate AND8, the tenth AND gate AND10, the twelfth AND gate AND12, the fourteenth AND gate AND14, and the sixteenth AND gate AND16 all output a low logic level. At this time, according to different first bit values A[4] and second bit values A[5], the 1st third selection signal YCA[0] and the 1st fourth selection signal YCB[0] are simultaneously at a high logic level, the 2nd third selection signal YCA[1] and the 2nd fourth selection signal YCB[1] are simultaneously at a high logic level, the 3rd third selection signal YCA[2] and the 3rd fourth selection signal YCB[2] are simultaneously at a high logic level, and the 4th third selection signal YCA[3] and the 4th fourth selection signal YCB[3] are simultaneously at a high logic level. Therefore, as shown in FIG. 4A and FIG. 4B, while the third switch circuit 142 selects the first sense amplifier groups SA00[7:0], SA10[7:0], and SA20[7:0] to respectively couple to the output data line groups DSA0[7:0] to DSA2[7:0], the fourth switch circuit 143 also selects the second sense amplifier group SA30[7:0] to couple to the output data line group DSA3[7:0], while the third switch circuit 142 selects the first sense amplifier groups SA01[7:0], SA11[7:0], and SA21[7:0] to respectively couple to the output data line groups DSA0[7:0] to DSA2[7:0], the fourth switch circuit 143 also selects the second sense amplifier group SA31[7:0] to couple to the output data line group DSA3[7:0], and so on. In other words, in a non-programming operation, 32 sense amplifiers may be selected at one time, and the corresponding 32 target memory cells (32 bits) may be operated accordingly.

When the flash memory device 100 is in the programming state, since the programming state signal APGM is at a high logic level, the first AND gate AND1, the third AND gate AND3, the fifth AND gate AND5, the seventh AND gate AND7, the nineteenth AND gate AND9, the eleventh AND gate AND11, the thirteenth AND gate AND13, and the fifteenth AND gate AND15 all output a low logic level. At this time, in the first stage ST1 (the flag signal FLAG is at a low logic level), all the fourth selection signals YCB[3:0] are at a low logic level, and according to different first bit values A[4] and second bit values A[5], one of the third selection signals YCA[3:0] is at a high logic level and the others are at a low logic level. For example, in the case where the first bit value A[4] is logic value 0 and the second bit value A[5] is logic value 0, the 1st third selection signal YCA[0] is at a high logic level, and the other three third selection signals YCA[1] to YCA[3] are at a low logic level. In the case where the first bit value A[4] is logic value 1 and the second bit value A[5] is logic value 0, the 2nd third selection signal YCA[1] is at a high logic level, and the other three third selection signals YCA[0], YCA[2], and YCA[3] are at a low logic level, and so on. Therefore, as shown in FIG. 4A, in the first stage ST1, the third switch groups 144_0 to 144_2 may respectively select one of the first sense amplifier groups SA00[7:0] to SA03[7:0], SA10[7:0] to SA13[7:0], and SA20[7:0] to SA23[7:0] to couple to the output data line groups DSA0[7:0] to DSA2[7:0] according to the received third selection signals YCA[3:0]. In other words, in the first stage ST1 of the programming operation, 24 sense amplifiers may be selected to couple to the output data line groups DSA0[7:0] to DSA2[7:0] at one time, and the corresponding 24 target memory cells may be applied with the programming voltage Vprg.

In addition, in the second stage ST2 (the flag signal FLAG is at a high logic level), all the third selection signals YCA[3:0] are at a low logic level, and according to different first bit values A[4], multiple of the fourth selection signals YCB[3:0] are at a high logic level, and the others are at a low logic level. For example, in the case where the first bit value A[4] is logic value 0, the 1st fourth selection signal YCB[0] and the 3rd fourth selection signal YCB[2] are at a high logic level, and the 2nd fourth selection signal YCB[1] and the 4th fourth selection signal YCB[3] are at a low logic level. In the case where the first bit value A[4] is logic value 1, the 2nd fourth selection signal YCB[1] and the 4th fourth selection signal YCB[3] are at a high logic level, and the 1st fourth selection signal YCB[0] and the 3rd fourth selection signal YCB[2] are at a low logic level. Therefore, as shown in FIG. 4B, in the second stage ST2, the fourth switch groups 145_0 and 145_1 may respectively select one of the second sense amplifier groups SA30[7:0] and SA31[7:0] and SA40[7:0] and SA41[7:0] to couple to the output data line groups DSA3[7:0] and DSA4[7:0] according to the received fourth selection signals YCB[3:0]. In other words, in the second stage ST2 of the programming operation, 16 sense amplifiers may be selected to couple to the output data line groups DSA3[7:0] and DSA4[7:0] at one time, and the corresponding 16 target memory cells may be applied with the programming voltage Vprg.

The memory controller 150 is coupled to the first decoder 120 and the second decoder 140. The memory controller 150 may provide the address signal ADR to the first decoder 120 and the second decoder 140, provide the flag signal FLAG to the second decoder 140, and apply the programming voltage Vprg to a target memory cell corresponding to a sense amplifier group selected by the second decoder 140. The programming voltage Vprg includes voltages applied to a gate node, a drain node, a source node, and a well region of the target memory cell and particularly refers to a voltage (VPPD) applied to the drain node through a selected bit line. For example, the voltage applied to the gate node may be 9 volts, the voltage applied to the drain node may be 4 volts, and the voltages applied to the source node and the well region may be 0 volt, but the disclosure is not limited thereto.

In addition to being a central processing unit (CPU), other programmable general-purpose or specific-purpose microprocessors, digital signal processors (DSP), programmable controllers, application specific integrated circuits (ASIC), programmable logic devices (PLD), other similar devices, or a combination of the devices, the memory controller 150 may also be a hardware circuit designed using a hardware description language (HDL) or any other digital circuit design manner known to persons skilled in the art and implemented through a manner such as a field programmable gate array (FPGA) or a complex programmable logic device (CPLD).

With the above circuit structure, the number of target memory cells (24) corresponding to the sense amplifiers selected in the first stage ST1 is greater than or equal to the number of target memory cells (16) corresponding to the sense amplifiers selected in the second stage ST2. In other words, the number of target memory cells to which the programming voltage Vprg may be applied in the first stage ST1 is greater than or equal to the number of target memory cells to which the programming voltage Vprg may be applied in the second stage ST2.

Furthermore, the maximum number of target memory cells (24) corresponding to the sense amplifiers selected in the first stage ST1 and the second stage ST2 may not be 2 to the power of N (where N is a positive integer greater than or equal to 1). In this way, it is not necessary to provide the number of bits that is 2 to the power of N for programming. In the case where the number of bits that may be simultaneously programmed is increased in order to reduce programming time, programming current does not need to be exponentially increased, thereby taking both programming speed and the programming current into consideration.

In addition, the target memory cells simultaneously applied with the programming voltage Vprg in the first stage ST1 are selected by one of the third selection signals YCA[3:0]. The target memory cells simultaneously applied with the programming voltage Vprg in the second stage ST2 are selected by multiple of the fourth selection signals YCB[3:0] (for example, the 1st fourth selection signal YCB[0] and the 3rd fourth selection signal YCB[2]).

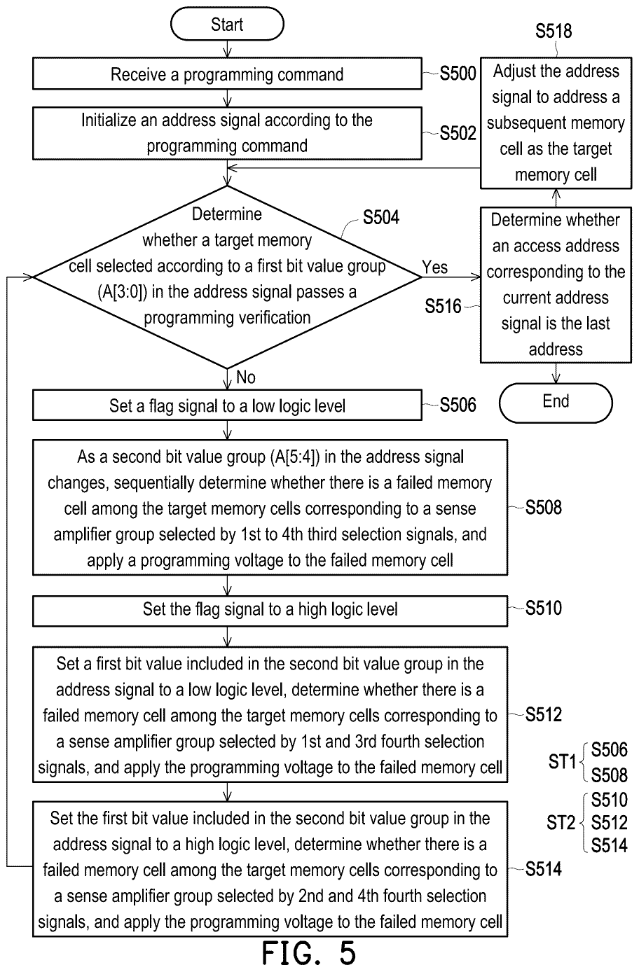

Please refer to FIG. 1, FIG. 3A, FIG. 3B, FIG. 4A, FIG. 4B, and FIG. 5 simultaneously. programming method of a flash memory device of the embodiment is applicable to the flash memory device 100 of FIG. 1. The following describes each step of the programming method of the embodiment in conjunction with each element in the flash memory device 100.

First, in step S500, the memory controller 150 receives a programming command CMD. Next, in step S502, the memory controller 150 initializes the address signal ADR according to the programming command CMD. Specifically, the memory controller 150 may designate a memory cell in the memory array 110 on which the programming operation is to be executed according to the received programming command CMD, and initialize the address signal ADR accordingly. The initialized address signal ADR is transmitted to the first decoder 120 and the second decoder 140 to select the memory cell on which the programming operation is to be executed.

In step S504, the memory controller 150 determines whether the target memory cell selected by the first decoder 120 according to the first bit value group A[3:0] in the address signal ADR passes the programming verification. For example, the memory controller 150 may determine whether a threshold voltage of each target memory cell selected by the first decoder 120 meets a specified range of each bit value in a specific data pattern. If the bit value in the data pattern is “0”, the threshold voltage of the corresponding memory cell must be greater than a preset programming verification reference voltage. If the bit value in the data pattern is “1”, the threshold voltage of the corresponding memory cell must be less than the preset programming verification reference voltage.

When not all the target memory cells selected by the first decoder 120 pass the programming verification, the process enters the first stage ST1. The first stage ST1 includes step S506 and step S508. In step S506, the memory controller 150 sets the flag signal FLAG to a low logic level. Next, as the second bit value group A[5:4] in the address signal ADR changes, the control circuit 141 converts the 1st third selection signal YCA[0] to the 4th third selection signal YCB[3] to a high logic level one by one, so that the target memory cells corresponding to the first sense amplifier group selected from the first sense amplifier groups SA00[7:0] to SA03[7:0], SA10[7:0] to SA 13[7:0], and SA20[7:0] to SA23[7:0] by the 1st third selection signal YCA[0] to the 4th third selection signal YCB[3] at the high logic level may be sequentially applied with the programming voltage Vprg. At the same time, in step S508, the memory controller 150 sequentially determines whether there is a failed memory cell among the target memory cells corresponding to the first sense amplifier group selected from the first sense amplifier groups SA00[7:0] to SA03[7:0], SA10[7:0] to SA13[7:0], and SA20[7:0] to SA23[7:0] by the 1st third selection signal YCA[0] to the 4th third selection signal YCA[3] at the high logic level, and applies the programming voltage Vprg to the failed memory cell. In the embodiment, the so-called “failed memory cell” refers to the memory cell that fails the programming verification among the target memory cells selected by the first decoder 120.

Next, the process enters the second stage ST2. The second stage ST2 includes step S510, step S512, and step S514. In step S510, the memory controller 150 sets the flag signal FLAG to a high logic level. Next, in step S512, the memory controller 150 sets the first bit value A[4] included in the second bit value group A[5:4] in the address signal ADR to a low logic level (logic value 0). At this time, the control circuit 141 converts the 1st fourth selection signal YCB[0] and the 3rd fourth selection signal YCB[2] to a high logic level, so that the target memory cells corresponding to the second sense amplifier groups SA30[7:0] and SA40[7:0] selected by the 1st fourth selection signal YCB[0] and the 3rd fourth selection signal YCB[2] at the high logic level may be applied with the programming voltage Vprg. At the same time, the memory controller 150 determines whether there is a failed memory cell among the target memory cells corresponding to the second sense amplifier groups SA30[7:0] and SA40[7:0] selected by the 1st fourth selection signal YCB[0] and the 3rd fourth selection signal YCB[2], and applies the programming voltage Vprg to the failed memory cell.

In step S514, the memory controller 150 sets the first bit value A[4] included in the second bit value group A[5:4] in the address signal ADR to a high logic level (logic value 1). At this time, the control circuit 141 converts the 2nd fourth selection signal YCB[1] and the 4th fourth selection signal YCB[3] to a high logic level, so that the target memory cells corresponding to the second sense amplifier groups SA31[7:0] and SA41[7:0] selected by the 2nd fourth selection signal YCB[1] and the 4th fourth selection signal YCB[3] at the high logic level may be applied with the programming voltage Vprg. At the same time, the memory controller 150 determines whether there is a failed memory cell among the target memory cells corresponding to the second sense amplifier groups SA31[7:0] and SA41[7:0] selected by the 2nd fourth selection signal YCB[1] and the 4th fourth selection signal YCB[3], and applies the programming voltage Vprg to the failed memory cell. Afterwards, the process returns to step S504 to continue processing.

When the memory controller 150 determines in step S504 that all the target memory cells selected by the first decoder 120 pass the programming verification, in step S516, the memory controller 150 determines whether an access address corresponding to the current address signal ADR is the last address on which the programming operation is to be executed. If yes, the programming method of the embodiment ends. If not, in step S518, the memory controller 150 adjusts the address signal ADR to address a subsequent memory cell as the target memory cell, and the process then returns to step S504 to continue processing.

It should be noted that the disclosure does not limit the number of components (for example, the sense amplifier groups, the switch circuits, and the switch groups) in the flash memory device 100. Persons skilled in the art may infer the number to be less or more according to actual requirements according to the teachings of the disclosure. In addition, the number of bits of the flag signal FLAG may also be adjusted accordingly.

In summary, the flash memory device of the disclosure may be programmed with the number of bits that is not 2 to the power of N. In this way, even if the number of bits to be simultaneously programmed is increased, the programming current does not need to be increased exponentially, thereby taking both the programming speed and the programming current into consideration.

What is claimed is:

1. A flash memory device, comprising:
a memory array, comprises a plurality of memory regions, wherein each of the memory regions comprises a plurality of memory cells;
a plurality of bit lines, respectively coupled to the memory cells;
a first decoder, coupled to the bit lines and configured to receive an address signal, and select a plurality of target memory cells from the memory cells according to the address signal;
a sense circuit, comprising a plurality of sense amplifiers, wherein an input terminal of each of the sense amplifiers is coupled to the first decoder; and
a second decoder, coupled to an output terminal of each of the sense amplifiers and configured to receive the address signal and a flag signal, divide the sense amplifiers into a plurality of sense amplifier groups, and sequentially select a plurality of the sense amplifier groups according to the address signal and the flag signal in a plurality of stages after failing a programming verification, so that the corresponding target memory cells are applied with a programming voltage,
wherein a number of the target memory cells corresponding to the sense amplifiers selected in one of the stages is greater than or equal to a number of the target memory cells corresponding to the sense amplifiers selected in others of the stages.

2. The flash memory device according to claim 1, wherein a maximum number of the target memory cells corresponding to the sense amplifiers selected in the stages is not 2 to the power of N, where N is a positive integer greater than or equal to 1.

3. The flash memory device according to claim 1, further comprising:
a memory controller, coupled to the first decoder and the second decoder, and configured to provide the address signal and the flag signal, and apply the programming voltage to the target memory cells corresponding to a plurality of the sense amplifier groups selected by the second decoder.

4. The flash memory device according to claim 1, wherein the first decoder comprises a plurality of common bit lines, a first switch circuit, and a second switch circuit, the first switch circuit comprises a plurality of first switch groups, the second switch circuit comprises a second switch group, each of the first switch groups is coupled between the corresponding bit lines and the corresponding common bit line, and the second switch group is coupled between the common bit lines and input terminals of the sense amplifiers.

5. The flash memory device according to claim 4, wherein the first decoder decodes the address signal to provide a plurality of first selection signals to each of the first switch groups and provide a plurality of second selection signals to the second switch group according to a first bit value group in the address signal, each of the first switch groups selects one of the corresponding bit lines to couple to the corresponding common bit line according to the first selection signals, and the second switch group selects one of the corresponding common bit lines to couple to the input terminal of the corresponding sense amplifier according to the second selection signals.

6. The flash memory device according to claim 1, wherein the second decoder comprises:
a control circuit, configured to decode the address signal to provide a plurality of third selection signals and a plurality of fourth selection signals according to a second bit value group in the address signal and the flag signal.

7. The flash memory device according to claim 6, wherein the stages comprise a first stage and a second stage, the target memory cells simultaneously applied with the programming voltage in the first stage are selected by one of the third selection signals, and the target memory cells simultaneously applied with the programming voltage in the second stage are selected by a plurality of the fourth selection signals.

8. The flash memory device according to claim 7, wherein the second bit value group comprises a first bit value and a second bit value, the flag signal is set to a low logic level in the first stage, as the first bit value and the second bit value in the address signal change, the control circuit converts a 1st to a 4th of the third selection signals into a high logic level one by one, so that the target memory cells corresponding to the sense amplifier groups selected by the 1st to the 4th of the third selection signals at the high logic level are sequentially applied with the programming voltage.

9. The flash memory device according to claim 7, wherein the second bit value group comprises a first bit value and a second bit value, the flag signal is set to a high logic level in the second stage, when the first bit value in the address signal is at a low logic level, the control circuit converts a 1st and a 3rd of the fourth selection signals to the high logic level, so that the target memory cells corresponding to the sense amplifier groups selected by the 1st and the 3rd of the fourth selection signals at the high logic level are applied with the programming voltage, and when the first bit value in the address signal is at the high logic level, the control circuit converts a 2nd and a 4th of the fourth selection signals to the high logic level, so that the target memory cells corresponding to the sense amplifier groups selected by the 2nd and the 4th of the fourth selection signals at the high logic level are applied with the programming voltage.

10. The flash memory device according to claim 6, further comprising a plurality of output data line groups, wherein the sense amplifier groups comprise a plurality of first sense amplifier groups and a plurality of second sense amplifier groups, the second decoder further comprises a third switch circuit and a fourth switch circuit, the third switch circuit comprises a plurality of third switch groups, the fourth switch circuit comprises a plurality of fourth switch groups, each of the third switch groups is coupled between the corresponding first sense amplifier groups and the corresponding output data line group, and each of the fourth switch groups is coupled between the corresponding second sense amplifier groups and the corresponding output data line group.

11. The flash memory device according to claim 10, wherein each of the third switch groups receives all of the third selection signals, and each of the fourth switch groups receives different ones of the fourth selection signals.

12. The flash memory device according to claim 11, wherein the stages comprise a first stage and a second stage, each of the third switch groups selects one of the corresponding first sense amplifier groups to couple to the corresponding output data line group according to the received third selection signals in the first stage, and each of the fourth switch groups selects one of the corresponding second sense amplifier groups to couple to the corresponding output data line group according to the received fourth selection signals in the second stage.

13. The flash memory device according to claim 7, further comprising:
a memory controller, coupled to the first decoder and the second decoder, and configured to set the flag signal to a low logic level in the first stage, sequentially determine whether there is at least one failed memory cell among the target memory cells corresponding to the sense amplifier groups selected by a 1st to a 4th of the third selection signals as the second bit value group in the address signal changes, and apply the programming voltage to the at least one failed memory cell.

14. The flash memory device according to claim 13, wherein the memory controller sets the flag signal to a high logic level in the second stage, sets a first bit value comprised in the second bit value group in the address signal to the low logic level, determines whether there is at least one failed memory cell among the target memory cells corresponding to the sense amplifier groups selected by a 1st and a 3^{rd} of the fourth selection signals, and applies the programming voltage to the at least one failed memory cell.

15. The flash memory device according to claim 13, wherein the memory controller sets the flag signal to a high logic level in the second stage, sets a first bit value comprised in the second bit value group in the address signal to the high logic level, determines whether there is at least one failed memory cell among the target memory cells corresponding to the sense amplifier groups selected by a 2nd and a 4th of the fourth selection signals, and applies the programming voltage to the at least one failed memory cell.
